(19) United States
(12) Patent Application Publication
(10) Pub. No.: US 2018/0175827 A1
(43) Pub. Date: Jun. 21, 2018

(54) LOW-PASS FILTER WITH SUPER SOURCE FOLLOWER AND TRANSMISSION ZERO CONTROLLING METHOD

(71) Applicants: National Taiwan University, Taipei (TW); MEDIATEK INC., Hsin-Chu City (TW)

(72) Inventors: Hsiao-Chin CHEN, Taipei (TW); Chi-Yin CHUNG, Taipei (TW)

(21) Appl. No.: 15/844,138

(22) Filed: Dec. 15, 2017

(30) Foreign Application Priority Data
Dec. 16, 2016 (TW) 105141891

(51) Int. Cl. H03H 11/12

(52) U.S. Cl. CPC H03H 11/1213

(57) ABSTRACT

A low-pass filter with a super source follower is disclosed. The low-pass filter includes biquad cells. Each biquad cell includes the super source follower, a first capacitor, a second capacitor and a zero controlling capacitor. The super source follower includes a first MOSFET and a second MOSFET. A gate electrode of first MOSFET is coupled to an input voltage. A source electrode of first MOSFET is coupled to a node between the first capacitor and the second capacitor. A drain electrode of first MOSFET is coupled to a gate electrode of second MOSFET. The zero controlling capacitor is coupled between the gate electrode and source electrode of first MOSFET, and the zero controlling capacitor has a capacitance far larger than a parasitic capacitance between the gate electrode and the source electrode of first MOSFET to generate a pair of controllable transmission zeros under low-frequency operation.

### BACKGROUND OF THE INVENTION

### 1. Field of the Invention

This invention relates to a filter, especially to a low-pass filter (LPF) with a super source follower and a transmission zero controlling method.

### 2. Description of the Prior Art

In general, when the conventional low-pass filter is operated under high-frequency, the transmission zero could appear in the frequency response diagram. No transmission zero will appear in the frequency response diagram when the conventional low-pass filter is operated under low-frequency.

If we want the transmission zero appears in the frequency response diagram when the conventional low-pass filter is operated under low-frequency, the width and the length of the metal-oxide-semiconductor field effect transistor (MOSFET) used for receiving the input voltage in the circuit may be designed very large; therefore, the parasitic capacitance (Cgs) between the gate electrode and the source electrode of the MOSFET will become larger to achieve the similar effect.

However, if the width and the length of the MOSFET used for receiving the input voltage in the circuit are designed very large, the volume of the MOSFET will become larger and additional designing and manufacturing cost will be also increased, it is not conducive to the market competitiveness of the low-pass filter.

### SUMMARY OF THE INVENTION

Therefore, the invention provides a low-pass filter with a super source follower and a transmission zero controlling method to solve the above-mentioned problems in the prior arts.

An embodiment of the invention is a low-pass filter with a super source follower. In this embodiment, the low-pass filter includes a plurality of biquad cells. Each of the plurality of biquad cells includes a first capacitor, a second capacitor, the super source follower and a zero controlling capacitor. The super source follower includes a first MOSFET and a second MOSFET. A gate electrode of the first MOSFET is coupled to an input voltage, a source electrode of the first MOSFET is coupled to a node between the first capacitor and the second capacitor, and a drain electrode of the first MOSFET is coupled to a gate electrode of the second MOSFET. The zero controlling capacitor is coupled between the gate electrode and the source electrode of the first MOSFET. The zero controlling capacitor has a capacitance far larger than a parasitic capacitance between the gate electrode and the source electrode of the first MOSFET to generate a pair of controllable transmission zeros when the low-pass filter with the super source follower is operated under low-frequency.

In an embodiment, a zero frequency corresponding to the pair of controllable transmission zeros is inversely proportional to a root value of the capacitance of the zero controlling capacitor.

In an embodiment, the plurality of biquad cells is coupled in series.

In an embodiment, the source electrode of the first MOSFET and a source electrode of the second MOSFET are coupled to an output voltage.

In an embodiment, one terminal of the first capacitor and the second capacitor coupled in series is coupled to a node between the drain electrode of the first MOSFET and the gate electrode of the second MOSFET and another terminal of the first capacitor and the second capacitor coupled in series is coupled to a ground terminal.

Another embodiment of the invention is a transmission zero controlling method. In this embodiment, the transmission zero controlling method is applied to a low-pass filter. The low-pass filter includes a super source follower, a first capacitor, a second capacitor and a zero controlling capacitor. The super source follower includes a first MOSFET and a second MOSFET coupled in series. A gate electrode of the first MOSFET is coupled to an input voltage, a source electrode of the first MOSFET is coupled to a node between the first capacitor and the second capacitor, and a drain electrode of the first MOSFET is coupled to a gate electrode of the second MOSFET. The transmission zero controlling method includes steps of: coupling the zero controlling capacitor between the gate electrode and the source electrode of the first MOSFET; and controlling a capacitance of the zero controlling capacitor far larger than a parasitic capacitance between the gate electrode and the source electrode of the first MOSFET to generate a pair of controllable transmission zeros when the low-pass filter with the super source follower is operated under low-frequency.

Compared to the prior art, the low-pass filter with a super source follower and a transmission zero controlling method of the invention can achieve the effect that the transmission zero appears in the frequency response diagram when the low-pass filter is operated under low-frequency without changing the size of the width and the length of the MOSFET used for receiving the input voltage and also change the zero frequency of the transmission zero by adjusting the capacitance of the zero controlling capacitor. Therefore, the low-pass filter with a super source follower and a transmission zero controlling method of the invention not only can generate transmission zero under high-frequency and low-frequency operations to have larger decay magnitude without affecting the corner frequency, but also can effectively overcome the drawbacks of larger volume and high cost in the prior art to increase the market competitiveness of the low-pass filter.

The advantage and spirit of the invention may be understood by the following detailed descriptions together with the appended drawings.

### BRIEF DESCRIPTION OF THE APPENDED DRAWINGS

FIG. 1 illustrates a schematic diagram of the low-pass filter including two biquad cells in a preferred embodiment of the invention.

FIG. 2 illustrates a circuit structure schematic diagram of the biquad cell in an embodiment of the invention.

FIG. 3 illustrates a frequency response diagram of the zero frequency of the transmission zero changing with the changed capacitance of the zero controlling capacitor.

FIG. 4 illustrates a flowchart of the transmission zero controlling method in another preferred embodiment of the invention.

### DETAILED DESCRIPTION OF THE INVENTION

A two-stage low-pass filter with super source follower in the invention includes a zero controlling capacitor to generate a pair of controllable transmission zeros to have larger decay magnitude without affecting the corner frequency and effectively overcome the drawbacks in the prior art to increase the market competitiveness of the low-pass filter with super source follower.

A preferred embodiment of the invention is a low-pass filter with super source follower. In this embodiment, the low-pass filter can includes a plurality of biquad cells. For example, as shown in FIG. 1, the low-pass filter 1 includes two biquad cells 10 and 12 and the biquad cells 10 and 12 are coupled in series, but not limited to this. The signal transmitted to the low-pass filter 1 will be inputted into the biquad cell 10 and outputted from the biquad cell 12.

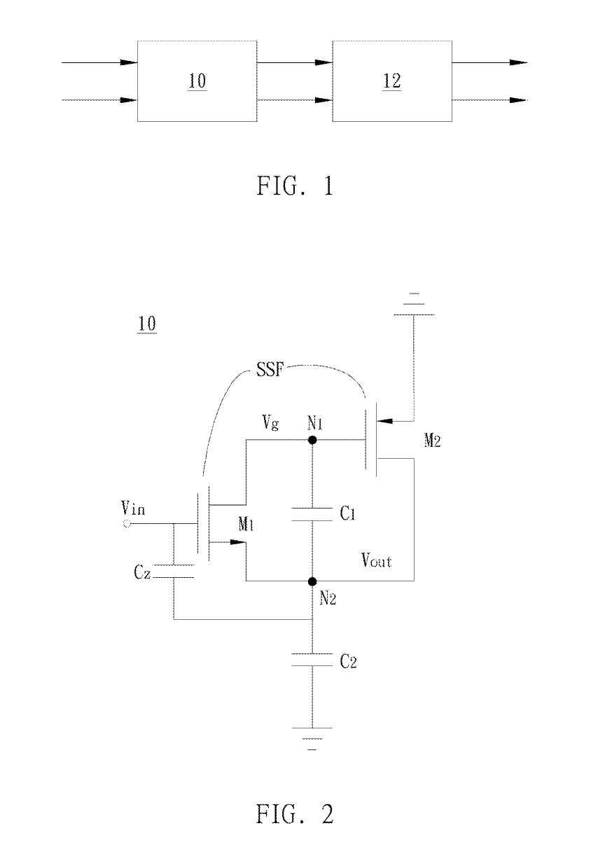

Then, please refer to FIG. 2. FIG. 2 illustrates a circuit structure schematic diagram of the biquad cell 10 in an embodiment.

As shown in FIG. 2, the biquad cell 10 can include a super source follower SSF, a first capacitor C1, a second capacitor C2 and a zero controlling capacitor Cz. Wherein, the super source follower SSF includes a first MOSFET M1 and a second MOSFET M2.

In this embodiment, the first capacitor C1 and the second capacitor C2 are coupled in series between a voltage Vg and a ground terminal; one terminal of the first capacitor C1 and the second capacitor C2 coupled in series is coupled to a first node N1 between a drain electrode of the first MOSFET M1 and a gate electrode of the second MOSFET M2; another terminal of the first capacitor C1 and the second capacitor C2 coupled in series is coupled to a ground terminal. A gate electrode of the first MOSFET M1 is coupled to an input voltage Vin; a source electrode of the first MOSFET M1 is coupled to a second node N2 between the first capacitor C1 and the second capacitor C2; the drain electrode of the first MOSFET M1 is coupled to the gate electrode of the second MOSFET M2. The source electrode of the first MOSFET M1 and the source electrode of the second MOSFET M2 are coupled to an output voltage Vout (namely the second node N2).

It should be noticed that the first MOSFET M1 is designed a small size without increasing its width and length. The zero controlling capacitor Cz is coupled between the gate electrode and the source electrode of the first MOSFET M1. The zero controlling capacitor Cz has a capacitance far larger than a parasitic capacitance (Cgs) between the gate electrode and the source electrode of the first MOSFET M1, so that the equivalent capacitance between the gate electrode and the source electrode of the first MOSFET M1 will be approximately equal to the capacitance of the zero controlling capacitor Cz.

Then, the transfer function of the circuit structure shown in FIG. 2 will be calculated as follows.

It is assumed that the resistance of the current source is large enough to be ignored, wherein f is the zero frequency; gm1 and gm2 are a transconductance of the first MOSFET M1 and a transconductance of the second MOSFET M2 respectively.

The first node N1: (Vg−Vout)*f*C1+gm1*(Vin−Vout)=0 Equation (1)

The second node N2: f*Cz*(Vin−Vout)+gm1*(Vin−Vout)+(Vg−Vout)*f*C1+gm2*Vg=f*C2*Vout Equation (2)

According to Equation (1): Vg=[−gm1*Vin+(gm1+f*C1)*Vout]/fC1 Equation (3)

According to Equation (2): Vg=[(gm1+f*C1+f*Cgs1+f*C2)*Vout−(gm1+f*Cz)*Vin]/(gm2+C1) Equation (4)

Since Equation (3)=Equation (4)=Vg, it can be obtained that

$$Vg = [ - gm 1 * Vin + ( gm 1 + f * C 1 ) * Vout ] / f * C 1 = [ ( gm 1 + f * C 1 + f * Cz + f * C 2 ) * Vout - ( gm 1 + f * Cz ) * Vin ] / ( gm 2 + f * C 1 ) \qquad Equation ( 5 )$$

Since the transmission zero is calculated, that is to say, Vout=0 and all terms including Vout can be ignored; therefore, it can be obtained according to Equation (5) that

gm1*gm2+gm1*f*C1=f*C*Cz+gm1*f*C1

$$f = \sqrt{\frac{gm 1 * gm 2}{C 1 * Cz}} \qquad Equation ( 6 )$$

It can be obtained according to Equation (6) that the zero frequency f corresponding to the transmission zero is inversely proportional to the root value of the capacitance of the zero controlling capacitor Cz.

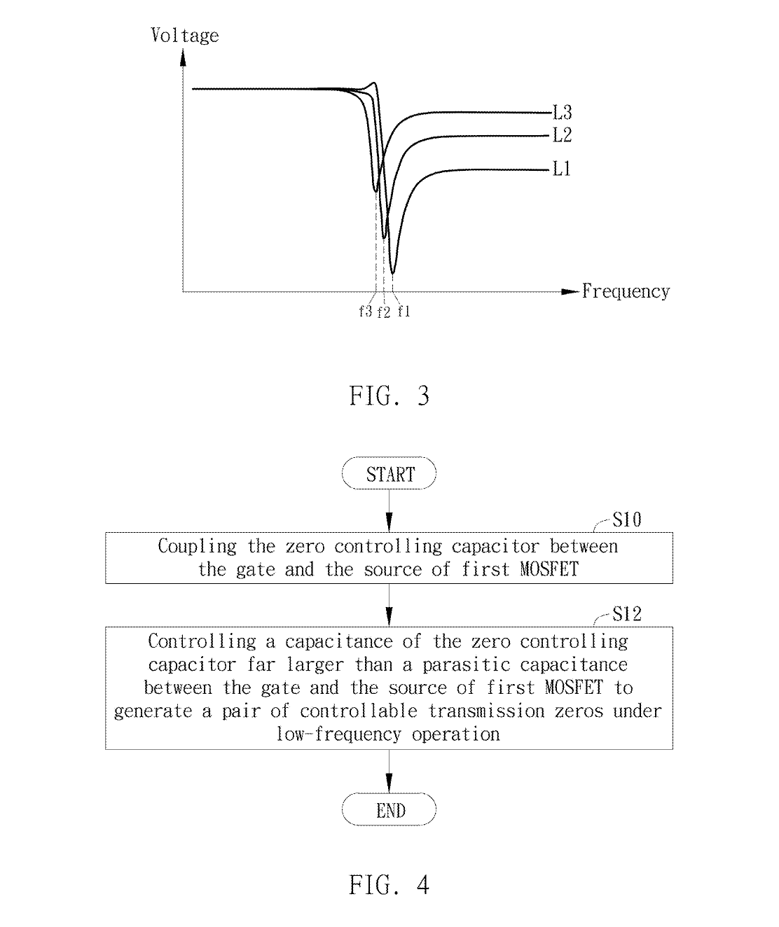

Please refer to FIG. 3. FIG. 3 illustrates a frequency response diagram of the zero frequency of the transmission zero changing with the changed capacitance of the zero controlling capacitor Cz.

As shown in FIG. 3, for example, L1˜L3 represent different frequency response curves when the capacitance of the zero controlling capacitor Cz is 1 pF, 2 pF and 4 pF respectively and corresponding zero frequencies of the transmission zero are f1˜f3 respectively. When the capacitance of the zero controlling capacitor Cz is magnified twice from 1 pF to 2 pF, the zero frequency will be changed from f1 to f2 and f2: f1 is approximately equal to 1/\sqrt{2} (namely 0.707). Therefore, the zero frequency that the transmission zero appears can be changed by adjusting the capacitance of the zero controlling capacitor Cz.

Another preferred embodiment of the invention is a transmission zero controlling method. In this embodiment, the transmission zero controlling method is applied to a low-pass filter. The low-pass filter includes a super source follower, a first capacitor, a second capacitor and a zero controlling capacitor. The super source follower includes a first MOSFET and a second MOSFET coupled in series. A gate electrode of the first MOSFET is coupled to an input voltage, a source electrode of the first MOSFET is coupled to a node between the first capacitor and the second capacitor, and a drain electrode of the first MOSFET is coupled to a gate electrode of the second MOSFET.

Please refer to FIG. 4. FIG. 4 illustrates a flowchart of the transmission zero controlling method in this embodiment.

As shown in FIG. 4, the transmission zero controlling method can include steps of:

Step S10: coupling the zero controlling capacitor between the gate electrode and the source electrode of the first MOSFET; and

Step S12: controlling a capacitance of the zero controlling capacitor far larger than a parasitic capacitance between the gate electrode and the source electrode of the first MOSFET to generate a pair of controllable transmission zeros when the low-pass filter with the super source follower is operated under low-frequency.

Compared to the prior art, the low-pass filter with a super source follower and a transmission zero controlling method of the invention can achieve the effect that the transmission zero appears in the frequency response diagram when the low-pass filter is operated under low-frequency without changing the size of the width and the length of the MOSFET used for receiving the input voltage and also change the zero frequency of the transmission zero by adjusting the capacitance of the zero controlling capacitor. Therefore, the low-pass filter with a super source follower and a transmission zero controlling method of the invention not only can generate transmission zero under high-frequency and low-frequency operations to have larger decay magnitude without affecting the corner frequency, but also can effectively overcome the drawbacks of larger volume and high cost in the prior art to increase the market competitiveness of the low-pass filter.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A low-pass filter with a super source follower, comprising:
a plurality of biquad cells, each of the plurality of biquad cells comprising:
a first capacitor,
a second capacitor coupled with the first capacitor in series;
the super source follower, comprising a first metal-oxide-semiconductor field effect transistor (MOSFET) and a second MOSFET, wherein a gate electrode of the first MOSFET is coupled to an input voltage, a source electrode of the first MOSFET is coupled to a node between the first capacitor and the second capacitor, and a drain electrode of the first MOSFET is coupled to a gate electrode of the second MOSFET; and
a zero controlling capacitor, coupled between the gate electrode and the source electrode of the first MOSFET, wherein the zero controlling capacitor has a capacitance far larger than a parasitic capacitance between the gate electrode and the source electrode of the first MOSFET to generate a pair of controllable transmission zeros when the low-pass filter with the super source follower is operated under low-frequency.

2. The low-pass filter with the super source follower of claim 1, wherein a zero frequency corresponding to the pair of controllable transmission zeros is inversely proportional to a root value of the capacitance of the zero controlling capacitor.

3. The low-pass filter with the super source follower of claim 1, wherein the plurality of biquad cells is coupled in series.

4. The low-pass filter with the super source follower of claim 1, wherein the source electrode of the first MOSFET and a source electrode of the second MOSFET are coupled to an output voltage.

5. The low-pass filter with the super source follower of claim 1, wherein one terminal of the first capacitor and the second capacitor coupled in series is coupled to a node between the drain electrode of the first MOSFET and the gate electrode of the second MOSFET and another terminal of the first capacitor and the second capacitor coupled in series is coupled to a ground terminal.

6. A transmission zero controlling method applied to a low-pass filter, the low-pass filter comprising a super source follower, a first capacitor, a second capacitor and a zero controlling capacitor, the super source follower comprising a first MOSFET and a second MOSFET coupled in series, a gate electrode of the first MOSFET being coupled to an input voltage, a source electrode of the first MOSFET being coupled to a node between the first capacitor and the second capacitor, and a drain electrode of the first MOSFET being coupled to a gate electrode of the second MOSFET, the transmission zero controlling method comprising steps of:
coupling the zero controlling capacitor between the gate electrode and the source electrode of the first MOSFET; and
controlling a capacitance of the zero controlling capacitor far larger than a parasitic capacitance between the gate electrode and the source electrode of the first MOSFET to generate a pair of controllable transmission zeros when the low-pass filter with the super source follower is operated under low-frequency.

7. The transmission zero controlling method of claim 6, wherein a zero frequency corresponding to the pair of controllable transmission zeros is inversely proportional to a root value of the capacitance of the zero controlling capacitor.

8. The transmission zero controlling method of claim 6, wherein the source electrode of the first MOSFET and a source electrode of the second MOSFET are coupled to an output voltage.

9. The transmission zero controlling method of claim 6, wherein one terminal of the first capacitor and the second capacitor coupled in series is coupled to a node between the drain electrode of the first MOSFET and the gate electrode of the second MOSFET and another terminal of the first capacitor and the second capacitor coupled in series is coupled to a ground terminal.
